(19) United States
(12) Patent Application Publication
(10) Pub. No.: US 2026/0095008 A1
(43) Pub. Date: Apr. 2, 2026

(54) ROUTING MEMBER, ELECTRICAL CONNECTION UNIT, AND METHOD FOR MANUFACTURING ROUTING MEMBER

(71) Applicant: YAZAKI CORPORATION, Tokyo (JP)

(72) Inventor: Yasuhiro Yamaguchi, Kakegawa-shi (JP)

(21) Appl. No.: 19/342,483

(22) Filed: Sep. 27, 2025

(30) Foreign Application Priority Data
Sep. 30, 2024 (JP) 2024-170236

(51) Int. Cl. H01R 25/16; H01R 43/048; H01R 43/16; H05K 7/20

(52) U.S. Cl. CPC H01R 25/161; H01R 43/0482; H01R 43/16; H05K 7/2049

(57) ABSTRACT

A routing member includes a bus bar and a heat storage member. The heat storage member is attached to the bus bar by a fixing portion formed by crimping.

### TECHNICAL FIELD

Embodiments of the present invention relate to a routing member, an electrical connection unit, and a method for manufacturing the routing member.

Priority is claimed on Japanese Patent Application No. 2024-170236 filed in Japan on Sep. 30, 2024, the content of which is incorporated herein by reference.

### BACKGROUND ART

An electrical connection unit including an electronic component and a bus bar electrically connected to the electronic component is known.

### Prior Art Document

### Patent Document

[Patent Document 1] Japanese Unexamined Patent Application, First Publication No. 2024-037492

### SUMMARY OF THE INVENTION

### Problems to be Solved by the Invention

It is expected to improve thermal characteristics of the electrical connection unit.

An embodiment provides a routing member, an electrical connection unit, and a method for manufacturing the routing member that can improve the thermal characteristics.

### Means for Solving the Problem

The routing member according to the embodiment includes a bus bar and a heat storage member. The heat storage member is attached to the bus bar by a fixing portion formed by crimping.

The electrical connection unit according to the embodiment includes a routing member and a connection target connected to the routing member. The routing member includes the bus bar and the heat storage member. The heat storage member is attached to the bus bar by a fixing portion formed by crimping.

A method for manufacturing a routing member according to an embodiment, the method including: forming a fixing hole in a first member that is one of a bus bar and a heat storage member; overlaying the first member with a second member that is the other one of the bus bar and the heat storage member; and deforming part of the second member by pressing to insert the part of the second member into the fixing hole, and fixing the bus bar and the heat storage member by crimping.

### Effects of Invention

According to the embodiment, the thermal characteristics can be improved.

### BRIEF DESCRIPTION OF THE DRAWINGS

FIG. 1 A cross-sectional view illustrating an electrical connection unit of a first embodiment.

FIG. 2 A perspective view illustrating a routing member according to the first embodiment.

FIG. 3 A view illustrating a fixing portion according to the first embodiment.

FIG. 4 A flowchart illustrating a method for manufacturing a routing member according to the first embodiment.

FIG. 5 A cross-sectional view illustrating a method for manufacturing a routing member according to the first embodiment.

FIG. 6 A view illustrating a fixing portion according to a second embodiment.

FIG. 7 A cross-sectional view illustrating a method for manufacturing a routing member according to the second embodiment.

FIG. 8 A perspective view illustrating a routing member according to a first modification example of the embodiment.

FIG. 9 A cross-sectional view illustrating an electrical connection unit according to a second modification example of the embodiment.

FIG. 10 A perspective view illustrating a heat storage member according to the second modification example of the embodiment.

### EMBODIMENTS FOR CARRYING OUT THE INVENTION

Hereinafter, embodiments will be described with reference to the drawings. In the following description, constitutions having the same or similar functions are denoted by the same reference numbers. Redundant descriptions of these constitutions may be omitted. The constitution to be described below does not limit the scope of the embodiment.

In the present disclosure, the terms are defined as follows. The term “connection” is not limited to a mechanical connection and may include an electrical connection. That is, the term “connection” is not limited to a case where two elements that are connection targets are directly connected and may include a case where two elements that are connection targets are connected with another element interposed therebetween. The term “facing” indicates that virtual projection images of two target objects overlap each other when viewed from a specific direction. That is, the term “facing” is not limited to a case where two target objects directly face each other and may include a case where two target objects face each other in a state in which another member exists between the two target objects. “Parallel”, “orthogonal”, or “the same” may include “substantially parallel”, “substantially orthogonal”, or “substantially the same”, respectively.

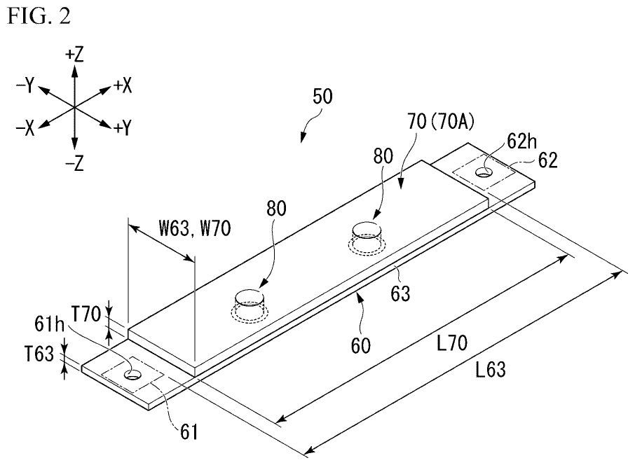

In the present disclosure, a +X direction, a −X direction, a +Y direction, a −Y direction, a +Z direction, and a −Z direction are defined as follows. The +X direction is, for example, an extension direction of at least part of an extension portion 63 of a bus bar 60 to be described later (see FIG. 2). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is, for example, the width direction of the extension portion 63 of the bus bar 60 (see FIG. 2). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the extension portion 63 of the bus bar 60 toward a heat storage member 70 to be described later (see FIG. 2). The −Z direction is a direction opposite to the +Z direction. Hereinafter, in a case where the +Z direction and the −Z direction are not distinguished, the directions will be simply referred to as “Z direction”.

### First Embodiment

### 1. Constitution of Electrical Connection Unit

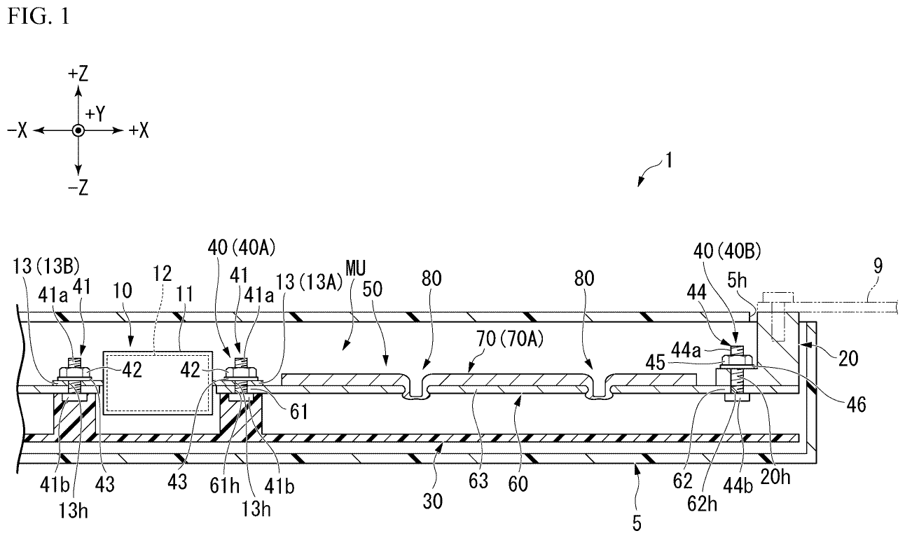

FIG. 1 is a cross-sectional view illustrating an electrical connection unit 1 according to a first embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device. The electrical connection unit 1 includes, for example, a housing 5 and a main body MU.

The housing 5 is a member forming the exterior of the electrical connection unit 1. The housing 5 is made of, for example, a synthetic resin and has an insulating property. The housing 5 accommodates the main body MU. The housing 5 has, for example, an opening 5h through which a connection component 20 for external connection is exposed. The housing 5 may be omitted.

The main body MU is a portion that performs a main function (for example, switching of electrical connection states or overcurrent protection) of the electrical connection unit 1. The main body MU may be referred to as a “circuit constitution body”. The main body MU includes, for example, one or more electronic components 10, a connection component 20, a base member 30, a plurality of fixing portions 40, and one or more routing members 50.

### 2. Electronic Component

First, an electronic component 10 will be described. The electronic component 10 is an electronic component mounted in accordance with a function required for the main body MU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. The type of the electronic component 10 is not limited to the above example. The electronic component 10 is, for example, a heat generating component that generates heat at the time of energization. The electronic component 10 includes, for example, a case 11, a component body 12, and a plurality of terminals 13.

The case 11 is an outer member that forms most of the outer shape of the electronic component 10. The case 11 is made of, for example, a synthetic resin and has an insulating property. The case 11 accommodates the component body 12. The case 11 and the component body 12 may be integrally formed.

The component body 12 is a portion that performs a main function of the electronic component 10. For example, in a case where the electronic component 10 is a relay, the component body 12 includes a switch (for example, a contact) that switches between a conductive state and a non-conductive state. For example, in a case where the electronic component 10 is a fuse, the component body 12 includes a fusion portion that is fused when an overcurrent flows. For example, in a case where the electronic component 10 is a capacitor, the component body 12 includes a portion that stores electric charge.

Each of the terminals 13 is an electrical connection portion exposed to the outside of the case 11. The terminal 13 is electrically connected to the component body 12 inside the case 11. In the present embodiment, the electronic component 10 includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side. One of the terminal 13A and the terminal 13B is an example of a “first terminal”. The other of the terminal 13A and the terminal 13B is an example of a “second terminal”.

Each terminal 13 has an attachment hole 13h into which a fastening member 41 (for example, a screw or a bolt) to be described later is inserted. The attachment hole 13h does not have, for example, screw grooves. The attachment hole 13h is, for example, a through hole penetrating the terminal 13 in the Z direction. In the present disclosure, the “attachment hole” is not limited to a hole having no screw grooves and may be a hole having screw grooves and engaging with the fastening member 41. In the present disclosure, the “attachment hole” is not limited to the through hole and may be a bottomed hole. For example, the attachment hole 13h may be a hole having screw grooves and engaged with a fastening member 44, or may be the bottomed hole.

### 3. Connection Component

Next, the connection component 20 will be described. The connection component 20 is a member for electrically connecting a plurality of members. The connection component 20 forms part of an energization path in the electrical connection unit 1. The connection component 20 is made of a metal (for example, made of copper, a copper alloy, aluminum, or an aluminum alloy). The connection component 20 has an attachment hole 20h into which a fastening member 44 to be described later is inserted. The attachment hole 20h does not have, for example, screw grooves. The attachment hole 20h is, for example, a through hole penetrating the connection component 20 in the Z direction. The attachment hole 20h may have screw grooves or may be the bottomed hole.

In the present embodiment, the connection component 20 is disposed between the routing member 50 and a bus bar 9 for external connection and electrically connects the routing member 50 and the bus bar 9. The bus bar 9 is a bus bar for electrically connecting the electrical connection unit 1 and an external device. In the present disclosure, the “external device” is an electrical device existing outside the electrical connection unit 1. The external device is, for example, a battery unit mounted on a vehicle or an inverter for driving a motor of the vehicle, but is not limited to these examples.

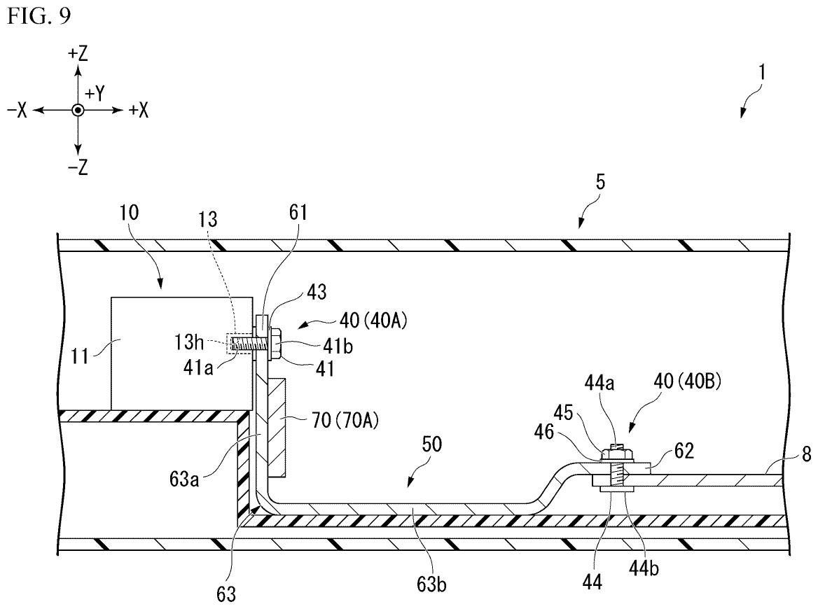

In the present disclosure, the “connection component” is not limited to the above-described examples. The connection component (for example, the connection component 20) may be a member that is disposed between the terminal 13 of another electronic component 10 and the routing member 50 and electrically connects the another electronic component 10 and the routing member 50. The connection component (for example, the connection component 20) may be a member that is disposed between two routing members 50 and electrically connects the two routing members 50. The connection component (for example, the connection component 20) may be a member that is disposed between a normal bus bar (see, for example, bus bar 8 to be described later and FIG. 9) and the routing member 50 in the electrical connection unit 1 and electrically connects the normal bus bar and the routing member 50.

### 4. Base Member

Next, the base member 30 will be described. The base member 30 is a support member that supports one or more of the electronic component 10, the connection component 20, and the routing member 50. The base member 30 is made of, for example, a synthetic resin and has an insulating property. In the present embodiment, the fastening member 41 and the fastening member 44 to be described later are fixed to the base member 30.

### 5. Fixing Portion

The fixing portion 40 is a fixing portion for fixing the routing member 50 and the connection target. A plurality of the fixing portions 40 include, for example, a first fixing portion 40A and a second fixing portion 40B.

### 5.1 First Fixing Portion

The first fixing portion 40A is a fixing portion that fixes a first connection portion 61 of the routing member 50 to be described later and a first connection target. The first fixing portion 40A includes, for example, a fastening member 41 (for example, a bolt or a screw), an engagement member 42 (for example, a nut), and a washer 43.

The fastening member 41 is, for example, a bolt having a shaft 41a and a head 41b. A circumferential surface of the shaft 41a has screw threads. The shaft 41a is passed through the washer 43 and is engaged with the engagement member 42. The head 41b has a diameter larger than that of the shaft 41a. In the present embodiment, the fastening member 41 is fixed to the base member 30 in an orientation in which the shaft 41a protrudes from the base member 30 in the +Z direction. The fastening member 41 is an example of a “first fastening member”. The first fixing portion 40A is not limited to the above-described example. The first fixing portion 40A is only required to have a structure for fixing the first connection portion 61 of the routing member 50 and the first connection target and is not limited to a specific structure.

### 5.2 Second Fixing Portion

The second fixing portion 40B is a fixing portion that fixes a second connection portion 62 of the routing member 50 and a second connection target. The second fixing portion 40B includes, for example, a fastening member 44 (for example, a bolt or a screw), an engagement member 45 (for example, a nut), and a washer 46.

The fastening member 44 is, for example, a bolt having a shaft 44a and a head 44b. A circumferential surface of the shaft 44a has screw threads. The shaft 44a is passed through the washer 46 and is engaged with the engagement member 45. The head 44b has a diameter larger than that of the shaft 44a. In the present embodiment, the fastening member 44 is fixed to the base member 30 in an orientation in which the shaft 44a protrudes from the base member 30 in the +Z direction. The fastening member 44 is an example of a “second fastening member”. The second fixing portion 40B is not limited to the above-described example. The second fixing portion 40B is only required to have a structure for fixing the second connection portion 62 of the routing member 50 and the second connection target and is not limited to a specific structure.

### 6. Routing Member

Next, the routing member 50 will be described.

FIG. 2 is a perspective view illustrating the routing member 50. The routing member 50 includes, for example, a bus bar 60 (a bus bar for energization) and a heat storage member 70 (for example, a bus bar 70A for heat storage).

### 6.1 Bus Bar for Energization

The bus bar 60 is a routing member for electrically connecting a plurality of connection targets. The bus bar 60 is made of a metal (for example, made of copper, a copper alloy, aluminum, or an aluminum alloy), and has electrical conductivity. The bus bar 60 electrically connects the first connection target and the second connection target. For example, the bus bar 60 electrically connects the electronic component 10 and the connection component 20. The electronic component 10 is an example of a “first connection target”. The connection component 20 is an example of a “second connection target”.

However, the first connection target and the second connection target are not limited to the above-described example. For example, the first connection target is any one of an electronic component, a connection component, another bus bar (for example, a normal bus bar 8 or a bus bar 60 included in another routing member 50) in the electrical connection unit 1, or a bus bar 9 for external connection. For example, the second connection target is any one of an electronic component, a connection component, another bus bar (for example, a normal bus bar 8 or a bus bar 60 included in another routing member 50) in the electrical connection unit 1, or a bus bar 9 for external connection. For example, the bus bar 60 may electrically connect the electronic component 10 (first connection target) and another electronic component 10 (second connection target). The bus bar 60 may electrically connect the connection component 20 (first connection target) and another connection component 20 (second connection target).

Hereinafter, as an example of the bus bar 60, the bus bar 60 that electrically connects the electronic component 10 (first connection target) and the connection component 20 (second connection target) will be described. However, in the following description, the descriptions of the “electronic component 10” and the “connection component 20” may be appropriately replaced with other members based on the intent described above.

As illustrated in FIG. 2, the bus bar 60 includes, for example, the first connection portion 61, the second connection portion 62, and the extension portion 63.

### First Connection Portion

The first connection portion 61 is a portion connected to the first connection target (for example, the electronic component 10). The first connection portion 61 is located at the middle of the bus bar 60 or at a first end of the bus bar 60. The first connection portion 61 is a portion facing the first fixing portion 40A (for example, a portion facing the fastening member 41, the engagement member 42, or the washer 43) when viewed from the Z direction. In the present embodiment, the first connection portion 61 is defined as a quadrangular region circumscribing the first fixing portion 40A when viewed from the Z direction (see FIG. 2).

The first connection portion 61 has a first attachment hole 61h into which the fastening member 41 is inserted. The attachment hole 61h does not have, for example, screw grooves. The attachment hole 61h is, for example, a through hole penetrating the first connection portion 61 in the Z direction. The attachment hole 61h is an example of a “first attachment hole”.

The attachment hole 61h of the first connection portion 61 overlaps the attachment hole 13h of the electronic component 10 in the Z direction. The fastening member 41 is inserted into the attachment hole 61h of the first connection portion 61 and the attachment hole 13h of the electronic component 10 along the Z direction. The engagement member 42 is engaged with the distal portion of the fastening member 41 inserted through the attachment hole 61h of the first connection portion 61 and the attachment hole 13h of the electronic component 10. With this constitution, the terminal 13 of the electronic component 10 and the first connection portion 61 are fixed. Instead of the above-described example, any one of the attachment hole 61h of the first connection portion 61 and the attachment hole 13h of the electronic component 10 may have screw grooves to be engaged with the fastening member 41. In this case, the engagement member 42 may be omitted.

### Second Connection Portion

The second connection portion 62 is a portion connected to the second connection target (for example, the connection component 20). The second connection portion 62 is located at the middle of the bus bar 60 or at a second end of the bus bar 60. The second connection portion 62 is a portion facing the second fixing portion 40B (for example, a portion facing the fastening member 44, the engagement member 45, or the washer 46) when viewed from the Z direction. In the present embodiment, the second connection portion 62 is defined as a quadrangular region circumscribing the second fixing portion 40B when viewed from the Z direction (see FIG. 2).

The second connection portion 62 has a second attachment hole 62h into which the fastening member 44 is inserted. The attachment hole 62h does not have, for example, screw grooves. The attachment hole 62h is, for example, a through hole penetrating the second connection portion 62 in the Z direction. The attachment hole 62h is an example of a “second attachment hole”.

The attachment hole 62h of the second connection portion 62 overlaps the attachment hole 20h of the connection component 20 in the Z direction. The fastening member 44 is inserted into the attachment hole 62h of the second connection portion 62 and the attachment hole 20h of the connection component 20 along the Z direction. The engagement member 45 is engaged with the distal portion of the fastening member 44 inserted through the attachment hole 62h of the second connection portion 62 and the attachment hole 20h of the connection component 20. With this constitution, the connection component 20 and the second connection portion 62 are fixed. Instead of the above-described example, any one of the attachment hole 62h of the second connection portion 62 and the attachment hole 20h of the connection component 20 may have screw grooves to be engaged with the fastening member 44. In this case, the engagement member 45 may be omitted.

### Extension Portion

The extension portion 63 is provided between the connection portion 61 and the connection portion 62. The extension portion 63 extends over the connection portion 61 and the connection portion 62. The extension portion 63 connects the connection portion 61 and the connection portion 62. In the example illustrated in FIG. 2, the extension portion 63 extends linearly in the X direction. However, the extension portion 63 may include a portion bent and extending in the Y direction or the Z direction. In this case, the “extension direction of the extension portion” is a direction along the extension portion 63 while being bent. The extension portion 63 is formed in, for example, a plate shape. A thickness direction (plate thickness direction) of the extension portion 63 is the Z direction. In the present embodiment, the entire bus bar 60 including the first connection portion 61, the second connection portion 62, and the extension portion 63 is formed in a plate shape.

### 6.2 Heat Storage Member (Bus Bar for Heat Storage)

Next, the heat storage member 70 will be described. The heat storage member 70 is a metal member attached to the bus bar 60. The heat storage member 70 is, for example, a member that stores (absorbs) at least part of heat generated by the first connection target or the second connection target and at least part of heat generated by the bus bar 60 itself. Instead of/in addition to the above-described example, the heat storage member 70 may be a member or the like that reduces thermal interference from an external device (bus bar 9 for external connection) to the electronic component 10. The heat storage member 70 is made of, for example, copper, a copper alloy, aluminum, or an aluminum alloy, but is not limited to these examples.

In the present embodiment, the heat storage member 70 is attached to the extension portion 63 of the bus bar 60. For example, the heat storage member 70 is provided to be separated from the first connection portion 61 and the second connection portion 62 of the bus bar 60. That is, the heat storage member 70 is provided in a region not overlapping the first fixing portion 40A and the second fixing portion 40B when viewed from the Z direction.

In the present embodiment, a bus bar 70A for heat storage is provided as an example of the heat storage member 70. The bus bar 70A for heat storage is a metal plate member disposed along the bus bar 60 for energization. The bus bar 70A for heat storage is disposed to overlap the bus bar 60 for energization from the Z direction.

In the present embodiment, the heat storage member 70 satisfying the following conditions is defined as the bus bar 70A for heat storage. That is, the heat storage member 70 has a thickness T70 as a thickness in a direction (Z direction) overlapping the extension portion 63 of the bus bar 60. The heat storage member 70 has a length L70 as a length in the extension direction (for example, in the X direction, hereinafter, simply referred to as a “extension direction”) of the extension portion 63 of the bus bar 60. The heat storage member 70 has a width W70 as a width in a direction (for example, in the Y direction, hereinafter, simply referred to as a “width direction”) orthogonal to the extension direction. In the present embodiment, the heat storage member 70 in which the length L70 and the width W70 are larger than the thickness T70 and the length L70 is larger than the width W70 is defined as a bus bar 70A for heat storage.

For example, the heat storage member 70 (the bus bar 70A for heat storage) is formed in a plate shape (flat shape) along the extension portion 63 of the bus bar 60. For example, the thickness T70 of the heat storage member 70 in the Z direction is smaller than the length L70 of the heat storage member 70 in the extension direction of the heat storage member 70. In the present embodiment, the thickness T70 of the heat storage member 70 in the Z direction is smaller than half of the length L70 of the heat storage member 70 in the extension direction. The width W70 of the heat storage member 70 in the Y direction is smaller than the length L70 of the heat storage member 70 in the extension direction. In the present embodiment, the width W70 of the heat storage member 70 in the Y direction is smaller than half of the length L70 of the heat storage member 70 in the extension direction.

The shape of the heat storage member 70 is not limited to the above-described example. For example, the width W70 of the heat storage member 70 in the Y direction may be larger than the length L70 of the heat storage member 70 in the extension direction. For example, the thickness T70 of the heat storage member 70 in the Z direction may be larger than at least one of the width W70 of the heat storage member 70 in the Y direction or the length L70 of the heat storage member 70 in the extension direction.

In the present embodiment, the heat storage member 70 is provided over half or more of the length of the extension portion 63 of the bus bar 60 in the extension direction. For example, the length L70 of the heat storage member 70 in the extension direction is larger than half of a length L63 of the extension portion 63 of the bus bar 60 in the extension direction.

In the present embodiment, the width W70 of the heat storage member 70 in the Y direction is larger than half of a width W63 of the extension portion 63 of the bus bar 60 in the Y direction. In the present embodiment, the width W70 of the heat storage member 70 in the Y direction is the same as the width W63 of the extension portion 63 of the bus bar 60 in the Y direction. The width W70 of the heat storage member 70 in the Y direction may be larger than the width W63 of the extension portion 63 of the bus bar 60 in the Y direction.

In the present embodiment, the thickness T70 of the heat storage member 70 in the Z direction is larger than the thickness T63 of the extension portion 63 of the bus bar 60 in the Z direction. In this constitution, it is easy to increase the heat capacity of the heat storage member 70 as compared with a case where the thickness T70 of the heat storage member 70 in the Z direction is smaller than the thickness T63 of the extension portion 63 of the bus bar 60 in the Z direction.

The thickness T70 of the heat storage member 70 in the Z direction may be the same as or smaller than the thickness T63 of the extension portion 63 of the bus bar 60 in the Z direction. In a case where the thickness T70 of the heat storage member 70 in the Z direction is smaller than the thickness T63 of the extension portion 63 of the bus bar 60 in the Z direction, it is easy to miniaturize (reduce the height of) the electrical connection unit 1.

### 6.3 Fixing Portion

Next, a fixing portion 80 will be described. The fixing portion 80 is a fixing portion that fixes the bus bar 60 and the heat storage member 70. The fixing portion 80 is disposed in a region overlapping the extension portion 63 of the bus bar 60 when viewed from the Z direction. That is, the fixing portion 80 is provided in a region separated from the first fixing portion 40A and the second fixing portion 40B when viewed from the Z direction.

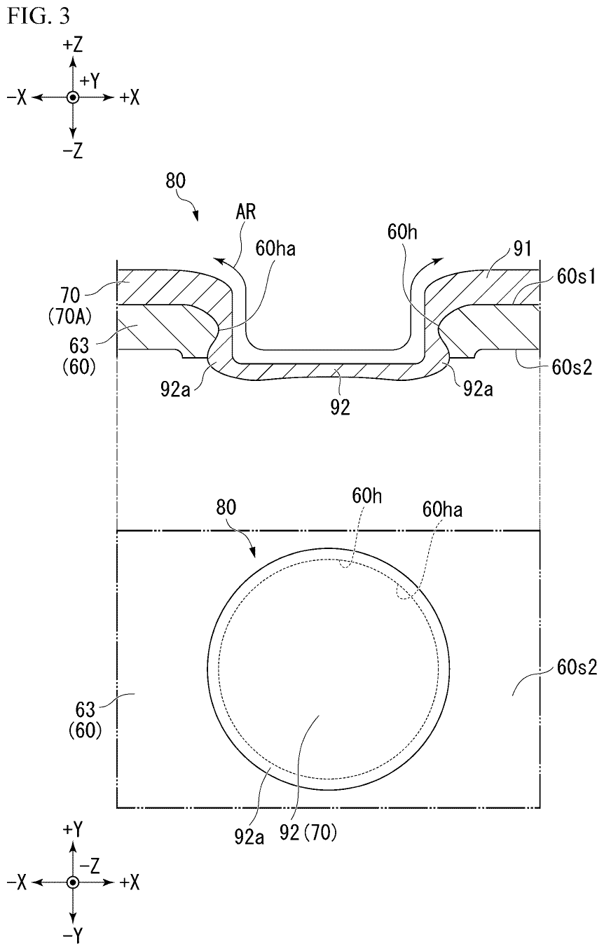

FIG. 3 is a view illustrating the fixing portion 80. In the present embodiment, the fixing portion 80 is a fixing portion that fixes the bus bar 60 and the heat storage member 70 by crimping. The fixing portion 80 is formed by, for example, part of the bus bar 60 and part of the heat storage member 70. The fixing portion 80 includes, for example, a fixing hole 60h formed in the extension portion 63 of the bus bar 60 and an insertion portion 92 provided in the heat storage member 70.

In the present embodiment, the extension portion 63 of the bus bar 60 has a first surface 60s1, a second surface 60s2, and a fixing hole 60h. The first surface 60s1 is a surface directed in the +Z direction. The first surface 60s1 faces the heat storage member 70. The second surface 60s2 is a surface directed in the −Z direction. The second surface 60s2 is located on the side opposite to the first surface 60s1.

The fixing hole 60h is, for example, a through hole penetrating the bus bar 60 in the Z direction. The fixing hole 60h extends through the first surface 60s1 and the second surface 60s2. However, the fixing hole 60h is not limited to the above-described example. The fixing hole 60h may be a bottomed recess recessed from the first surface 60s1 in the −Z direction. The fixing hole 60h is, for example, circular, but may be polygonal, elliptical, or the like.

On the other hand, the heat storage member 70 includes a main body 91 and an insertion portion 92. The main body 91 is a plate portion provided along the first surface 60s1 of the bus bar 60. The main body 91 is disposed to overlap the first surface 60s1 of the bus bar 60 from the +Z direction side.

The insertion portion 92 protrudes from the main body 91 toward the −Z direction side and is inserted into the fixing hole 60h of the bus bar 60. The insertion portion 92 is in contact with the inner circumferential surface of the fixing hole 60h of the bus bar 60 and is fitted into the fixing hole 60h of the bus bar 60. In the present embodiment, the insertion portion 92 is in contact with the inner circumferential surface of the fixing hole 60h of the bus bar 60, and thus the contact area between the bus bar 60 and the heat storage member 70 is enlarged (see an arrow AR in FIG. 3). For example, the insertion portion 92 protrudes from the inside of the fixing hole 60h toward the −Z direction side beyond the second surface 60s2 of the bus bar 60.

In the present embodiment, the insertion portion 92 has a bulging portion 92a located on the −Z direction side relative to the minimum inner diameter portion 60ha of the fixing hole 60h. The bulging portion 92a bulges in the X direction or the Y direction relative to the minimum inner diameter portion 60ha of the fixing hole 60h. The bulging portion 92a is located on the side opposite to the main body 91 relative to part of the bus bar 60 in the Z direction. Part of the bus bar 60 is clamped in the Z direction between the main body 91 and the bulging portion 92a of the heat storage member 70.

In the present embodiment, the insertion portion 92 is part of the heat storage member 70. The insertion portion 92 is formed, for example, by deforming part of the heat storage member 70 which is a plate member. The insertion portion 92 is formed by, for example, part of the heat storage member 70 being pressed toward the fixing hole 60h of the bus bar 60 and deformed so as to follow the inner circumferential surface of the fixing hole 60h. In the present embodiment, by fitting the insertion portion 92 into the fixing hole 60h of the bus bar 60, the fixing portion 80 is formed by crimping and fixing.

### 6. Method for Manufacturing Routing Member 50

Next, a method for manufacturing the routing member 50 will be described.

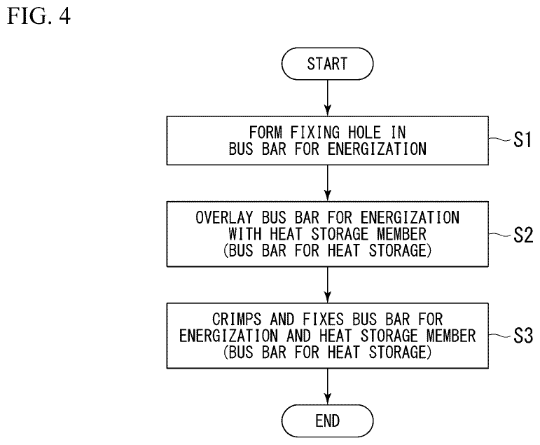

FIG. 4 is a flowchart illustrating a method for manufacturing the routing member 50. In the present embodiment, the bus bar 60 is an example of a “first member”. The heat storage member 70 is an example of a “second member”.

First, the fixing hole 60h is formed in the bus bar 60 (step S1). The fixing hole 60 is formed by, for example, press working. In the present disclosure, “forming the fixing hole in the bus bar” may include a case where the fixing hole is simultaneously formed when the bus bar is formed.

Next, the bus bar 60 and the heat storage member 70 (bus bar 70A for heat storage) are disposed in an overlapping manner (step S2). Next, part of the heat storage member 70 is deformed by pressing and inserted into the fixing hole 60h of the bus bar 60, and thus the bus bar 60 and the heat storage member 70 are fixed by crimping (step S3). Through these steps, the routing member 50 is completed.

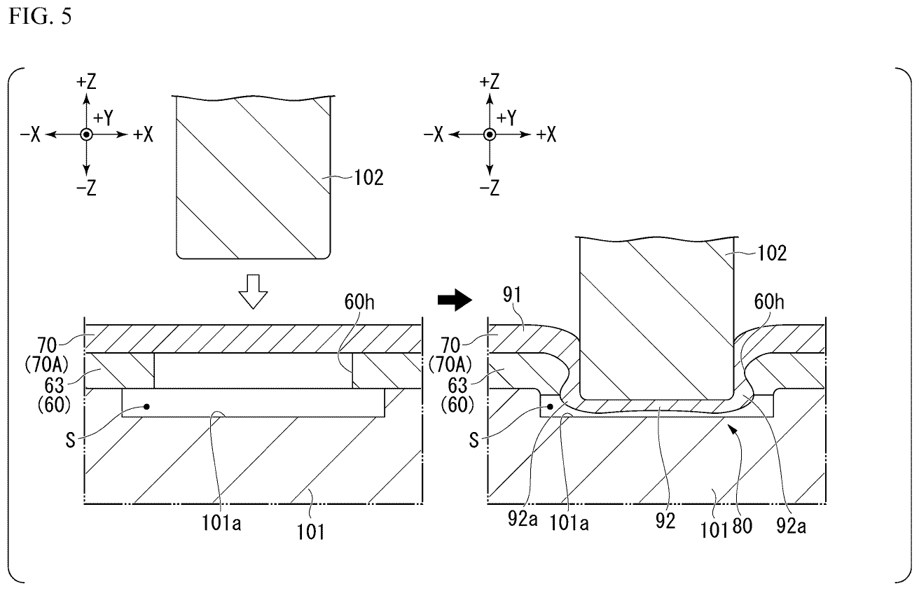

FIG. 5 is a cross-sectional view illustrating a method for manufacturing the routing member 50. FIG. 5 illustrates a process of step S3 described above. In the present embodiment, in the process of step S3, a die 101 and a punch 102 are used.

The die 101 is disposed on the side (−Z direction side) opposite to the heat storage member 70 relative to the bus bar 60. The die 101 has a recess 101a in a portion corresponding to the fixing hole 60h of the bus bar 60. The dimension of the recess 101a in the X direction and the Y direction is larger than the fixing hole 60h of the bus bar 60. The recess 101a forms a space S, in which the heat storage member 70 is deformable, between the bus bar 60 and the die 101.

The punch 102 is disposed on the side opposite to the die 101 relative to the bus bar 60 and the heat storage member 70. The punch 102 is disposed corresponding to the fixing hole 60h of the bus bar 60. The punch 102 has, for example, an outer shape (for example, a diameter) smaller than the fixing hole 60h of the bus bar 60. When the punch 102 is moved toward the die 101, part of the heat storage member 70 is deformed by pressing and inserted into the fixing hole 60h of the bus bar 60 to form the insertion portion 92. Through this process, part of heat storage member 70 inserted through the minimum inner diameter portion 60ha of the fixing hole 60h bulges in the X direction or the Y direction to form the bulging portion 92a. Through this process, the fixing portion 80 is formed, and the bus bar 60 and the heat storage member 70 are fixed by crimping.

### 7. Examples

Next, examples regarding a combination of materials of the bus bar 60 and the heat storage member 70 will be described.

### 7.1 First Example

In the first example, the bus bar 60 is made of aluminum or an aluminum alloy. The heat storage member 70 is made of copper or a copper alloy. Here, the specific heat of copper is smaller than the specific heat of aluminum. In the above-described constitution, since the material of the bus bar 60 is aluminum or an aluminum alloy while the material of the heat storage member 70 is copper or a copper alloy, it is possible to ensure the heat storage capability of the routing member 50 while suppressing the volume of the routing member 50 for miniaturization (for example, reduction in height). With this constitution, it is possible to miniaturize (for example, reduce the height of) the electrical connection unit 1 while improving the thermal characteristics of the electrical connection unit 1.

### 7.2 Second Example

In a second example, the bus bar 60 is made of aluminum or an aluminum alloy. The heat storage member 70 is made of aluminum or an aluminum alloy. Here, the specific gravity of the aluminum is smaller than that of the copper. In the above-described constitution, since the material of the bus bar 60 is aluminum or an aluminum alloy while the material of the heat storage member 70 is aluminum or an aluminum alloy, it is possible to ensure the heat storage capability of the routing member 50 while suppressing the weight of the routing member 50. With this constitution, it is possible to reduce the weight of the electrical connection unit 1 while improving the thermal characteristics of the electrical connection unit 1.

### 8. Advantages

As a first comparative example, a structure in which the heat storage member 70 does not exist will be considered. In such a structure, in a case where sufficient heat capacity is not ensured in the electrical connection unit, a large temperature rise may occur in part of the electrical connection unit, and/or thermal interference to the first connection target or the second connection target may increase. For example, when a large transient current flows, a large temperature rise may occur in part of the electrical connection unit and/or thermal interference to the first connection target or the second connection target may increase. Therefore, it may be difficult to improve the thermal characteristics of the electrical connection unit.

On the other hand, in the present embodiment, the routing member 50 includes the bus bar 60 and the heat storage member 70. The bus bar 60 includes the first connection portion 61 connected to the first connection target, the second connection portion 62 connected to the second connection target, and the extension portion 63 extending between the first connection portion 61 and the second connection portion 62. The heat storage member 70 is attached to the extension portion 63 of the bus bar 60.

In such a constitution, the heat storage member 70 increases the heat capacity of the bus bar 60. Since the heat storage member 70 increases the heat capacity of the bus bar 60 in this manner, part of the heat transmitted through the bus bar 60 can be stored (absorbed) at least temporarily by the heat storage member 70. In this structure, it is possible to suppress occurrence of the large temperature rise in part of the electrical connection unit 1 and/or the increase in thermal interference to the first connection target or the second connection target. By this operation, it is possible to improve the thermal characteristics (for example, heat dissipation or heat storage capability) of the electrical connection unit 1.

As a second comparative example, a structure in which the bus bar 60 and the heat storage member 70 are fixed by a fixing portion using a fastening member such as a bolt will be considered. In the structure of this comparative example, the contact area between the bus bar 60 and the heat storage member 70 is small at the fixing portion, and there is room for improvement from the viewpoint of thermal characteristics.

In the present embodiment, the routing member 50 includes the bus bar 60 and the heat storage member 70 attached to the bus bar 60 by the fixing portion 80 formed by crimping. In such a constitution, as compared with the structure of the above-described comparative example, it is easy to ensure the large contact area between the bus bar 60 and the heat storage member 70. In this structure, the bus bar 60 and the heat storage member 70 can be thermally firmly connected. By this operation, the thermal characteristics of the electrical connection unit 1 can be improved.

In the present embodiment, the heat storage member 70 is a plate member provided along the bus bar 60. In such a constitution, the heat storage member 70 is easily deformed, and the bus bar 60 and the heat storage member 70 are easily fixed by crimping. With this constitution, the manufacturability of the routing member 50 can be improved.

In the present embodiment, the fixing portion 80 includes the fixing hole 60h formed in the bus bar 60, and the insertion portion 92 which is part of the heat storage member 70 and is inserted into the fixing hole 60h of the bus bar 60. In such a constitution, it is possible to fix the bus bar 60 and the heat storage member 70 by crimping while ensuring a large volume (heat capacity) of the heat storage member 70. Thus, the thermal characteristics of the electrical connection unit 1 can be further improved through further improvement of heat dissipation by the heat storage member 70.

In the present embodiment, the bus bar 60 has the first surface 60s1 facing the heat storage member 70 and the second surface 60s2 located on the side opposite to the first surface 60s1. The fixing hole 60h of the bus bar 60 is a through hole extending through the first surface 60s1 and the second surface 60s2. The insertion portion 92 of the heat storage member 70 protrudes from the inside of the fixing hole 60h of the bus bar 60 beyond the second surface 60s2 of the bus bar 60. In such a constitution, since the fixing hole 60h of the bus bar 60 is a through hole, the insertion portion 92 of the heat storage member 70 is easily deformed through the fixing hole 60h at the time of crimping and fixing. By this operation, for example, as compared with a case where the fixing hole 60h is a bottomed hole, the heat storage member 70 can be deformed even with a relatively small force, and the bus bar 60 and the heat storage member 70 can be fixed by crimping. With this constitution, the manufacturability of the routing member 50 can be further improved.

### Second Embodiment

Next, a second embodiment will be described. The second embodiment is different from the first embodiment in that a fixing hole 70h is formed in the heat storage member 70 and the insertion portion 92 is provided in the bus bar 60. Constitutions other than those to be described below are the same as the constitutions of the first embodiment.

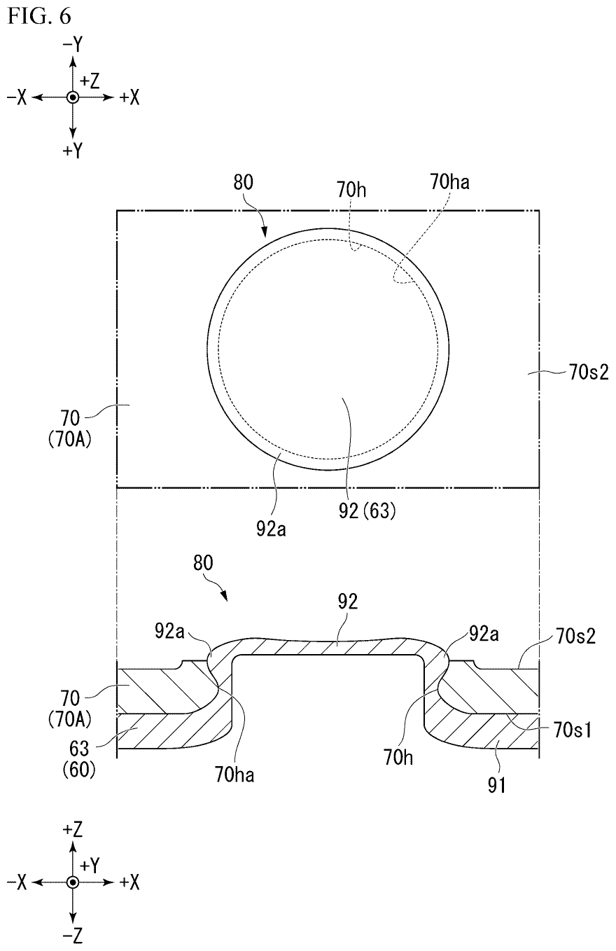

FIG. 6 is a view illustrating the fixing portion 80 according to the second embodiment. In the present embodiment, the fixing portion 80 is a fixing portion that fixes the bus bar 60 and the heat storage member 70 by crimping. The fixing portion 80 includes, for example, the fixing hole 70h formed in the heat storage member 70 (bus bar 70A for heat storage) and the insertion portion 92 provided in the extension portion 63 of the bus bar 60.

In the present embodiment, the heat storage member 70 (bus bar 70A for heat storage) has a first surface 70s1, a second surface 70s2, and the fixing hole 70h. The first surface 70s1 is a surface directed in the −Z direction. The first surface 70s1 faces the extension portion 63 of the bus bar 60. The second surface 70s2 is a surface directed in the +Z direction. The second surface 70s2 is located on the side opposite to the first surface 70s1.

The fixing hole 70h is, for example, a through hole penetrating the heat storage member 70 (bus bar 70A for heat storage) in the Z direction. The fixing hole 70h extends through the first surface 70s1 and the second surface 70s2. However, the fixing hole 70h is not limited to the above-described example. The fixing hole 70h may be a bottomed recess recessed from the first surface 70s1 in the +Z direction. The fixing hole 70h is, for example, circular, but may be polygonal, elliptical, or the like.

On the other hand, the extension portion 63 of the bus bar 60 includes the main body 91 and the insertion portion 92. The main body 91 is a plate portion provided along the first surface 70s1 of the heat storage member 70. The main body 91 is disposed to overlap the first surface 70s1 of the heat storage member 70 from the −Z direction side.

The insertion portion 92 protrudes from the main body 91 toward the +Z direction side and is inserted into the fixing hole 70h of the heat storage member 70. The insertion portion 92 is in contact with the inner circumferential surface of the fixing hole 70h of the heat storage member 70 and is fitted into the fixing hole 70h of the heat storage member 70. In the present embodiment, the insertion portion 92 is in contact with the inner circumferential surface of the fixing hole 70h of the heat storage member 70, and thus the contact area between the bus bar 60 and the heat storage member 70 is enlarged. For example, the insertion portion 92 protrudes from the inside of the fixing hole 70h toward the +Z direction side beyond the second surface 70s2 of the heat storage member 70.

In the present embodiment, the insertion portion 92 has a bulging portion 92a located on the +Z direction side relative to the minimum inner diameter portion 70ha of the fixing hole 70h. The bulging portion 92a bulges in the X direction or the Y direction relative to the minimum inner diameter portion 70ha of the fixing hole 70h. The bulging portion 92a is located on the side opposite to the main body 91 relative to part of the heat storage member 70 in the Z direction. Part of the heat storage member 70 is clamped in the Z direction between the main body 91 and the bulging portion 92a of the bus bar 60.

In the present embodiment, the insertion portion 92 is part of the extension portion 63 of the bus bar 60. The insertion portion 92 is formed, for example, by deforming part of the extension portion 63 of the bus bar 60 which is a plate member. The insertion portion 92 is formed by, for example, part of the extension portion 63 of the bus bar 60 being pressed toward the fixing hole 70h of the heat storage member 70 and deformed so as to follow the inner circumferential surface of the fixing hole 70h. In the present embodiment, by fitting the insertion portion 92 into the fixing hole 70h of the heat storage member 70, the fixing portion 80 is formed by crimping and fixing.

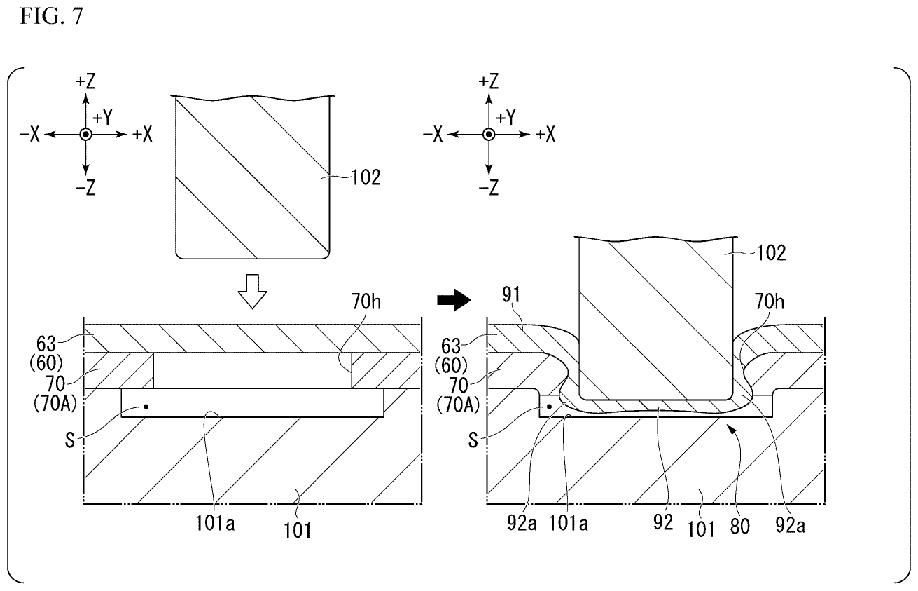

FIG. 7 is a cross-sectional view illustrating a method for manufacturing the routing member 50 according to the present embodiment. The method for manufacturing the routing member 50 according to the present embodiment is similar to that of the routing member 50 according to the first embodiment. In the description of the method for manufacturing the routing member 50 according to the present embodiment, the “bus bar 60” and the “extension portion 63” may be replaced with the “heat storage member 70”, the “fixing hole 60h” may be replaced with the “fixing hole 70h”, and the “heat storage member 70” may be replaced with the “extension portion 63 of the bus bar 60” in the description of the method of manufacturing the routing member 50 according to the first embodiment described above. In the present embodiment, the heat storage member 70 is an example of a “first member”. The bus bar 60 is an example of a “second member”.

In the second embodiment, the fixing portion 80 includes the fixing hole 70h formed in the heat storage member 70, and the insertion portion 92 which is part of the extension portion 63 of the bus bar 60 and is inserted into the fixing hole 70h of the heat storage member 70. In such a constitution, it is possible to fix the bus bar 60 and the heat storage member 70 by crimping while ensuring the large energization area of the extension portion 63 of the bus bar 60. Thus, the electrical characteristics of the electrical connection unit 1 can be improved through improvement of the electrical characteristics of the routing member 50. Since the fixing hole 60h is not provided in the bus bar 60, for example, the amount of heat generated by the bus bar 60 itself can be reduced as compared with a case where the fixing hole 60h is provided in the bus bar 60. By this operation, the thermal characteristics of the electrical connection unit 1 can be further improved.

In the present embodiment, the heat storage member 70 has the first surface 70s1 facing the extension portion 63 of the bus bar 60 and the second surface 70s2 located on the side opposite to the first surface 70s1. The fixing hole 70h of the heat storage member 70 is a through hole extending through the first surface 70s1 and the second surface 70s2. The insertion portion 92 of the extension portion 63 of the bus bar 60 protrudes from the inside of the fixing hole 70h of the heat storage member 70 beyond the second surface 70s2 of the heat storage member 70. In such a constitution, since the fixing hole 70h of the heat storage member 70 is a through hole, the insertion portion 92 of the bus bar 60 is easily deformed through the fixing hole 70h at the time of crimping and fixing. By this operation, for example, as compared with a case where the fixing hole 70h is a bottomed hole, the bus bar 60 can be deformed even with a relatively small force, and the bus bar 60 and the heat storage member 70 can be fixed by crimping. With this constitution, the manufacturability of the routing member 50 can be further improved.

### MODIFICATION EXAMPLES

Some modification examples of the first embodiment or the second embodiment will be described below. A constitution other than that to be described below in each modification example is the same as the constitution of the first embodiment or the second embodiment. In each modification example to be described below, the fixing portion 80 may be the same fixing portion 80 as that in the first embodiment, or may be the same fixing portion 80 as that in the second embodiment.

### First Modification Example

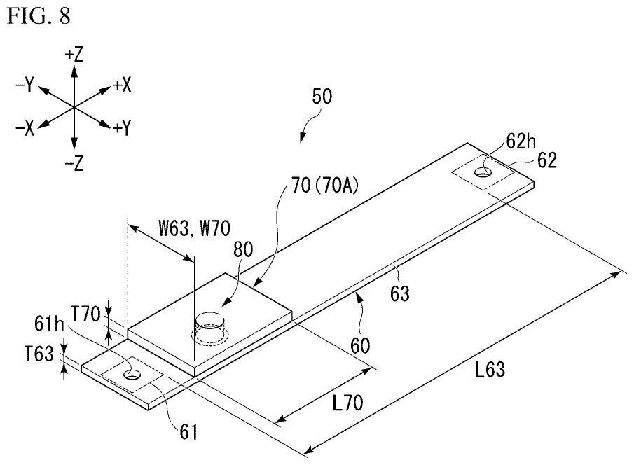

FIG. 8 is a perspective view illustrating the routing member 50 according to a first modification example. In the first modification example, the length L70 of the heat storage member 70 in the extension direction is equal to or less than half of the length L63 of the extension portion 63 of the bus bar 60 in the extension direction. The heat storage member 70 is provided corresponding to only part of the extension portion 63 of the bus bar 60. Even with such a constitution, the thermal characteristics of the electrical connection unit 1 can be improved.

### Second Modification Example

FIG. 9 is a perspective view illustrating an electrical connection unit 1 according to a second modification example. In the present embodiment, the bus bar 60 electrically connects the electronic component 10 and another bus bar 9 included in the electrical connection unit 1. The electronic component 10 is an example of a “first connection target”. The bus bar 9 is an example of a “second connection target”.

In the present modification example, the extension portion 63 includes a first extension portion 63a (first portion) and a second extension portion 63b (second portion).

The first extension portion 63a is adjacent to the first connection portion 61 and extends from the first connection portion 61. In the present modification example, the first connection portion 61 is a plate portion provided along the Z direction and the Y direction. For example, the first extension portion 63a extends from the first connection portion 61 in the −Z direction. For example, the first extension portion 63a is a plate portion provided along the Z direction and the Y direction.

The second extension portion 63b is located on the side opposite to the first connection portion 61 relative to the first extension portion 63a. The second extension portion 63b is located between the first extension portion 63a and the second connection portion 62. The second extension portion 63b is bent and extends from the first connection portion 61. The second extension portion 63b extends, for example, in the +X direction from the end of the first extension portion 63a in the −Z direction. For example, the second extension portion 63b is a plate portion provided along the X direction and the Y direction.

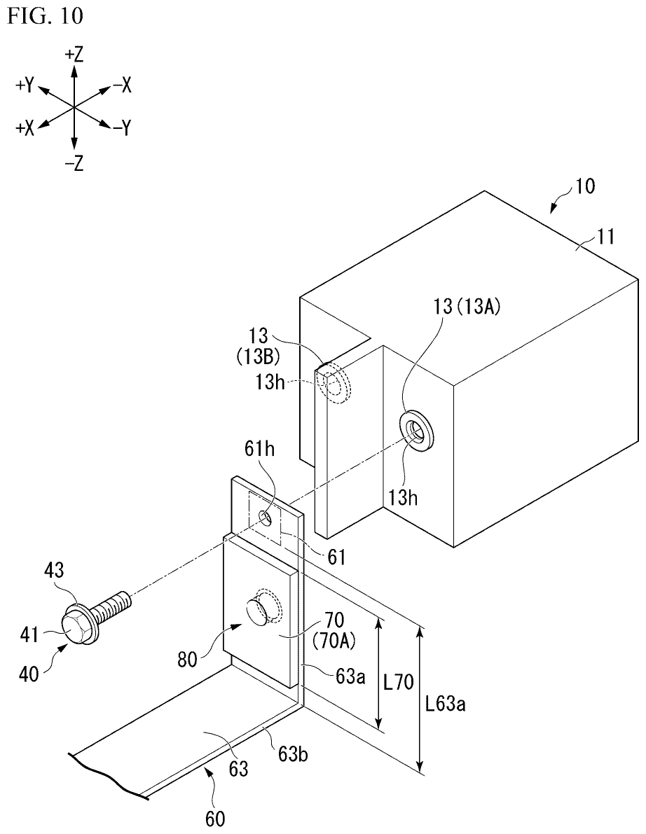

FIG. 10 is a perspective view illustrating the heat storage member 70 according to the second modification example. In the present modification example, the heat storage member 70 (bus bar 70A for heat storage) is attached to the first extension portion 63a. The heat storage member 70 (the bus bar 70A for heat storage) is formed in a plate shape (flat shape) along the first extension portion 63a of the bus bar 60. The heat storage member 70 is provided over half or more of the length of the first extension portion 63a of the bus bar 60 in the extension direction. That is, the length L70 of the heat storage member 70 in the extension direction is larger than half of a length L63a of the first extension portion 63a of the bus bar 60 in the extension direction.

In the present modification example, the heat storage member 70 is not attached to the second extension portion 63b. In other words, the heat storage member 70 is disposed closer to the electronic component 10 (for example, heat generation target) than the boundary between the first extension portion 63a and the second extension portion 63b.

In the constitution of the second modification example as described above, it is possible to improve the thermal characteristics of the electrical connection unit 1 as in the first embodiment or the second embodiment.

Several embodiments and modification examples have been described above. However, the embodiments and the modification examples are not limited to the examples described above. For example, a plurality of modification examples described above may be implemented in combination with each other.

### DESCRIPTION OF REFERENCE SYMBOLS

1 Electrical connection unit
10 Electronic component
20 Connection component
40 Fixing portion
40A First fixing portion
40B Second fixing portion
41 Fastening member (first fastening member)
44 Fastening member (second fastening member)
50 Routing member
60 Bus bar (bus bar for energization)
60h Fixing hole
61 First connection portion
61h Attachment hole
62 Second connection portion
62h Attachment hole
63 Extension portion
63a First extension portion (first portion)
63b Second extension portion (second portion)
70 Heat storage member
70A Bus bar for heat storage
70h Fixing hole
91 Main body
92 Insertion portion

1. A routing member comprising:
a bus bar; and
a heat storage member attached to the bus bar by a fixing portion formed by crimping.

2. The routing member according to claim 1,
wherein the heat storage member is a plate member provided along the bus bar.

3. The routing member according to claim 2,
wherein the fixing portion includes
a fixing hole formed in the bus bar, and
an insertion portion that is part of the heat storage member and is inserted into the fixing hole.

4. The routing member according to claim 3,
wherein the bus bar has a first surface facing the heat storage member and a second surface located on a side opposite to the first surface, and the fixing hole is a through hole extending through the first surface and the second surface, and
the insertion portion protrudes from an inside of the fixing hole beyond the second surface.

5. The routing member according to claim 2,
wherein the fixing portion includes
a fixing hole formed in the heat storage member, and
an insertion portion that is part of the bus bar and is inserted into the fixing hole.

6. The routing member according to claim 5,
wherein the heat storage member has a first surface facing the bus bar and a second surface located on a side opposite to the first surface, and the fixing hole is a through hole extending through the first surface and the second surface, and
the insertion portion protrudes from an inside of the fixing hole beyond the second surface.

7. An electrical connection unit comprising:
the routing member according to claim 1; and
a connection target connected to the routing member.

8. A method for manufacturing a routing member, the method comprising:
forming a fixing hole in a first member that is one of a bus bar and a heat storage member;
overlaying the first member with a second member that is the other one of the bus bar and the heat storage member; and
deforming part of the second member by pressing to insert the part of the second member into the fixing hole and fixing the bus bar and the heat storage member by crimping.
